(19) United States
(12) Patent Application Publication
(10) Pub. No.: US 2025/0227870 A1
(43) Pub. Date: Jul. 10, 2025

(54) HOLDING MECHANISM AND ELECTRONIC DEVICE

(71) Applicant: Wistron Corp., New Taipei City (TW)

(72) Inventors: Jun-Hao WANG, New Taipei City (TW); Hua Jun LIANG, New Taipei City (TW); Zhao Ping FU, New Taipei City (TW)

(21) Appl. No.: 18/613,459

(22) Filed: Mar. 22, 2024

(30) Foreign Application Priority Data
Jan. 4, 2024 (CN) 202410017754.1

(51) Int. Cl. H05K 7/14

(52) U.S. Cl. CPC H05K 7/1489

(57) ABSTRACT

A holding mechanism is provided, and includes a frame, a carrier, and a bracket. The frame is used to accommodate an electronic component. The carrier is affixed to the frame. The bracket has a sliding rail. The carrier is connected to the bracket via the sliding rail so that the frame may be rotated relative to the frame. Accordingly, additional electronic components can be disposed above the chassis, and the convenience of installing or removing electronic components can be improved.

### CROSS REFERENCE TO RELATED APPLICATIONS

This application claims priority of China Patent Application No. 202410017754.1, filed on Jan. 4, 2024, the entirety of which is incorporated by reference herein.

### BACKGROUND

### Technical Field

The disclosure is related to a holding mechanism and an electronic device, and in particular it is related to a holding mechanism and an electronic device that are movable for installation or removal of the electronic component.

### Description of the Related Art

With the advancements being made in modern technology, electronic apparatuses have found wider categories. Large electronic apparatuses, such as computers and servers in particular, have gradually become indispensable parts of daily life. These electronic apparatuses are usually equipped with electronic devices (such as a chassis) to accommodate additional electronic components and provide more functionality. However, current electronic devices still have room for improvement in terms of the inconvenience of installing or removing electronic components.

### BRIEF SUMMARY

The present disclosure provides a holding mechanism. The holding mechanism includes a frame, a carrier, and a bracket. The frame is used to accommodate an electronic component. The carrier is affixed to the frame. The bracket has a sliding rail. The carrier is connected to the bracket via the sliding rail so that the frame is used to rotate relative to the frame.

The present disclosure provides an electronic device. The electronic device includes a chassis, a fixed bracket, and a holding mechanism. The chassis has a bottom surface and a sidewall that is perpendicular to the bottom surface. The fixed bracket is affixed on the sidewall. The holding mechanism is movably connected to the fixed bracket and includes a frame used to accommodate an electronic component, a holder affixed to the frame, and a bracket movably disposed between the sidewall of the chassis and the fixed bracket. The bracket has a slide rail, and the holder is movably connected to the bracket via the slide rail, so that the holding mechanism is used to rotate relative to the chassis.

### BRIEF DESCRIPTION OF THE DRAWINGS

The disclosure may be more fully understood by reading the subsequent detailed description and examples with references made to the accompanying drawings, wherein:

FIG. 1 illustrates a perspective view of an electronic device in accordance with some embodiments of the present disclosure.

FIG. 2 illustrates a perspective view of a holding mechanism in accordance with some embodiments of the present disclosure.

FIG. 3 illustrates an exploded view of the holding mechanism in accordance with some embodiments of the present disclosure.

FIG. 4 illustrates a perspective view of the holding mechanism in accordance with some embodiments of the present disclosure.

FIG. 5 illustrates a side view of the holding mechanism in accordance with some embodiments of the present disclosure.

FIG. 6 illustrates a side view of the holding mechanism in accordance with some embodiments of the present disclosure.

FIGS. 7A through 7D illustrate schematic views of various stages of operating the holding mechanism in accordance with some embodiments of the present disclosure.

FIG. 8 illustrates a partial perspective view of the electronic device in accordance with some embodiments of the present disclosure.

FIG. 9 illustrates a perspective view of a holding mechanism in accordance with some embodiments of the present disclosure.

FIGS. 10A through 10D illustrate schematic views of various stages of the operation of the holding mechanism in accordance with some embodiments of the present disclosure.

### DETAILED DESCRIPTION OF THE INVENTION

The holding mechanism and the electronic device of some embodiments of the present disclosure are described in the following description. However, it should be appreciated that the following detailed description of some embodiments of the disclosure provides various concepts of the present disclosure which may be performed in specific backgrounds that may vary widely. The specific embodiments disclosed are provided merely to clearly describe the usage of the present disclosure by some specific methods without limiting the scope of the present disclosure.

In addition, relative terms such as “down” or “bottom,” “up” or “top” may be used in the following embodiments in order to describe the relationship between one element and another element in the figures. It should be appreciated that if the device shown in the figures is flipped upside-down, the element located on the “down” side may become the element located on the “up” side.

It should be understood that although the terms “first,” “second,” etc. may be used herein to describe various elements, materials and/or portions, these elements, materials and/or portions are not limited by the above terms. These terms merely serve to distinguish different elements, materials and/or portions. Therefore, a first element, material and/or portion may be referred to as a second element, material and/or portion without departing from the teaching of some embodiments in the present disclosure. Unless defined otherwise, the first or second element, material and/or portion in the claims may be interpreted as any element, material and/or portion in the specification as long as it conforms to the description in the claims.

Unless defined otherwise, all terms (including technical and scientific terms) used herein have the same meaning as commonly understood by one of ordinary skill in the art to which the present disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure. In addition, the terms “substantially,” “approximately” or “about” may also be recited in the present disclosure, and these terms are intended to encompass situations or ranges that is substantially or exact the same as the description herein. It should be noted that unless defined specifically, even if the above terms are not recited in the description, it should be read as the same meaning as those approximate terms are recited.

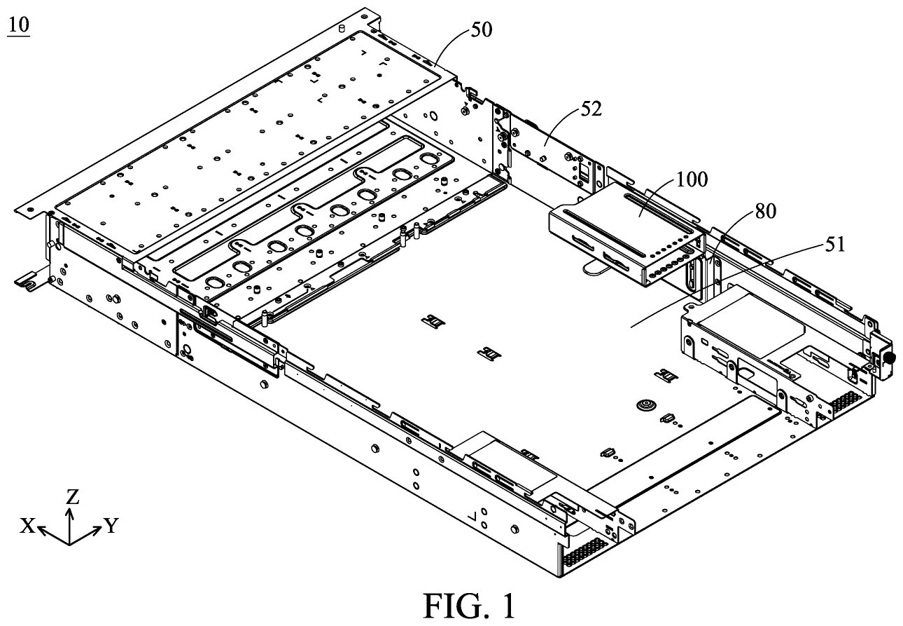

First, referring to FIG. 1, which illustrates a perspective view of an electronic device 10 in accordance with some embodiments of the present disclosure. It should be noted that the electronic device 10 can be any suitable electronic device, such as computer equipment, server equipment, etc., but the present disclosure is not limited thereto. In some embodiments, the present disclosure merely illustrates a part of the electronic device 10, and any electronic device that may include this part is included within the scope of the present disclosure. As shown in FIG. 1, the electronic device 10 includes a chassis 50 and a holding mechanism 100. The chassis 50 may include a bottom surface 51 and a sidewall 52. The sidewall 52 is connected to the bottom surface 51. The sidewall 52 is perpendicular to the bottom surface 51. Electronic components (not shown) may be disposed on the bottom surface 51 of the chassis 50. The electronic components can be any type of electronic components, depending on the function to be achieved, and therefore will not be discussed in detail below. In some embodiments, a fixed bracket 80 is disposed on the sidewall 52 of the chassis 50, whereby the holding mechanism 100 can be disposed on the sidewall 52. The holding mechanism 100 can be used to accommodate additional electronic components without directly disposing the above-mentioned electronic components on the bottom surface 51. As a result, additional electronic components can be disposed in the space above the electronic components which are disposed on the bottom surface 51 of the chassis 50 without affecting other components originally disposed on the bottom surface 51. To be more specific, when the holding mechanism 100 overlaps the bottom surface 51 of the chassis 50 in a third direction (for example, the Z direction), the holding mechanism 100 is in a storage state.

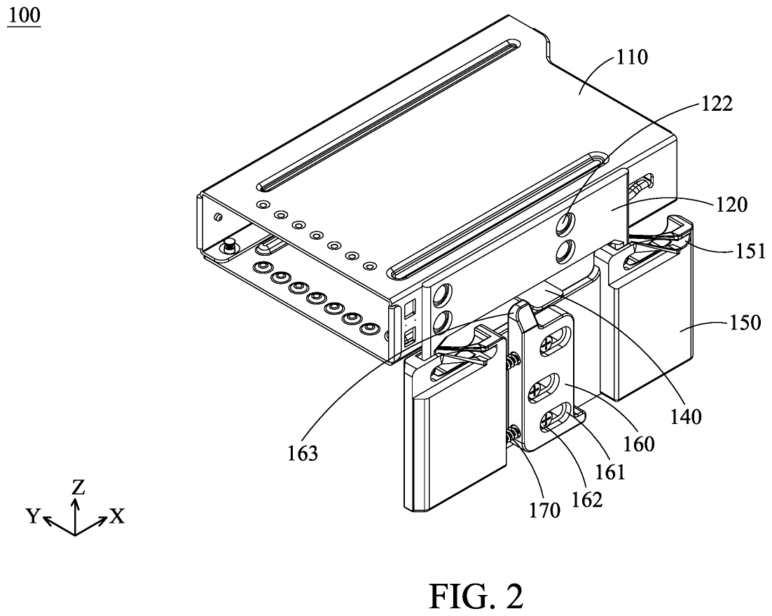

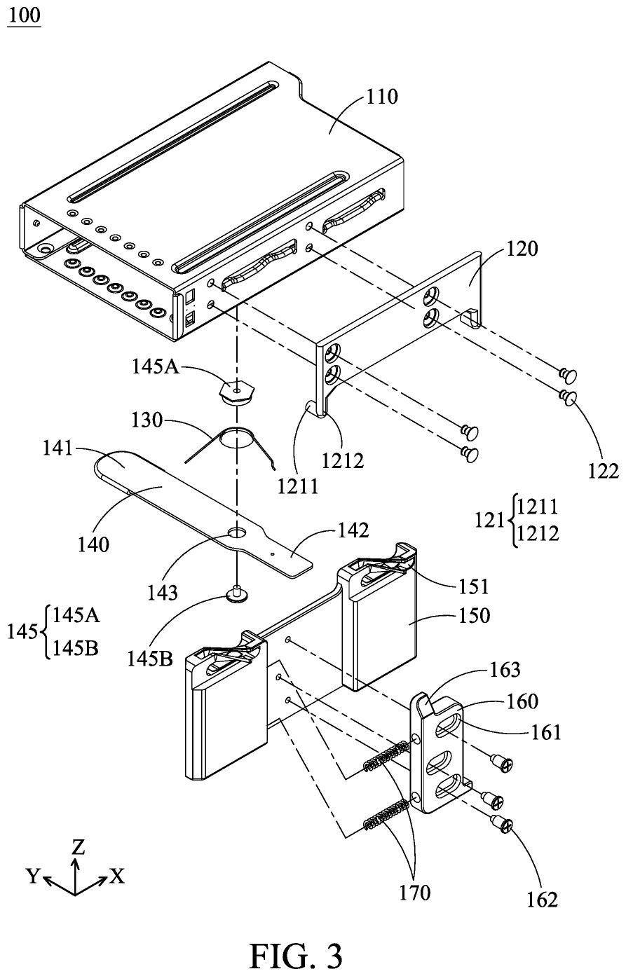

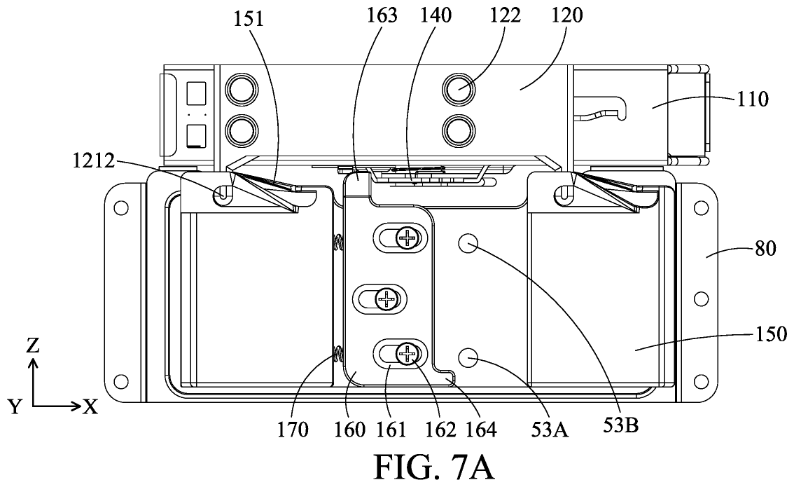

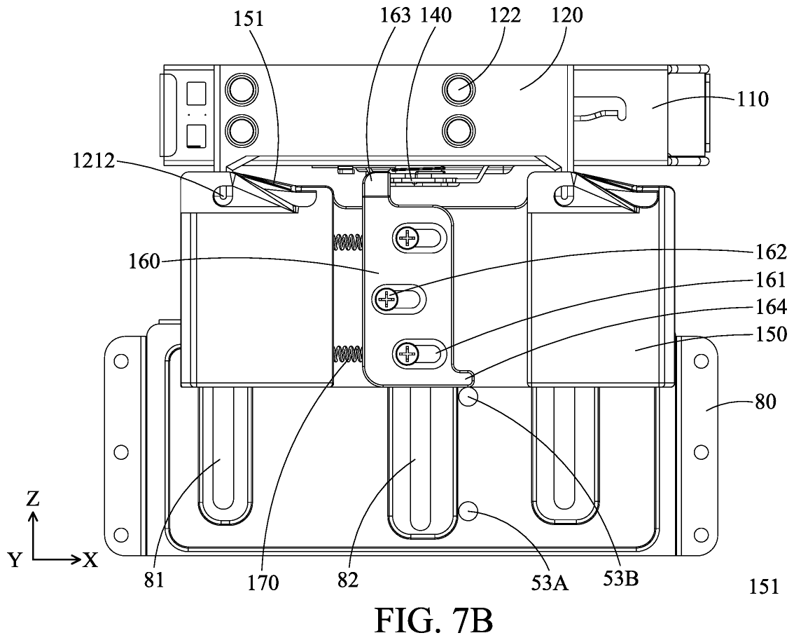

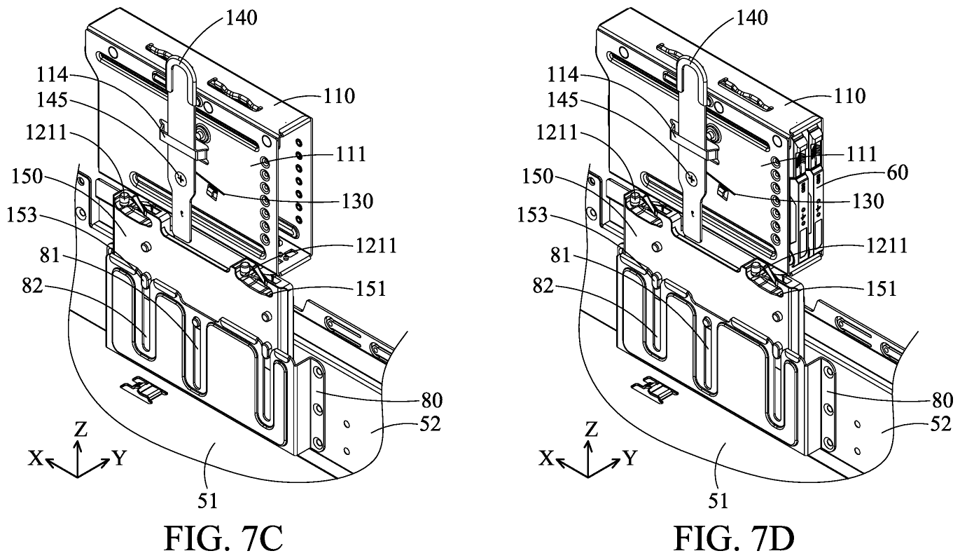

FIG. 2 illustrates a perspective view of the holding mechanism 100 in accordance with some embodiments of the present disclosure. FIG. 3 illustrates an exploded view of the holding mechanism 100 in accordance with some embodiments of the present disclosure. As shown in FIGS. 2 and 3, the holding mechanism 100 may include a frame 110, a holder 120, a torsion member 130, a handle 140, a bracket 150, a sliding member 160 and an elastic element 170. In some embodiments, the frame 110 defines a carrying space that is used to accommodate at least one electronic component (for example, the electronic component 60 shown in FIG. 7D). The holder 120 is affixed to the frame 110 via, for example, a fixing member 122. For example, the fixing members 122 may be a bolt or other elements that are used to affix the frame 110 and the holder 120. In some embodiments, the holder 120 may include a connecting portion 121 so as to connect to the bracket 150. The connecting portion 121 includes a first section 1211 and a second section 1212. The frame 110 is used to rotate relative to the bracket 150 to the unfolded state while the connecting portion 121 serves as a fulcrum. When the holding mechanism 100 is in the storage state, the frame 110 abuts against the sliding rail 151 (that is, in contact with the bracket 150) via the first section 1211. When the holding mechanism 100 is in the unfolded state, the frame 110 abuts against the sliding rail 151 (that is, in contact with the bracket 150) via the second section 1212. For example, the connecting portion 121 can be L-shaped (that is, the first section 1211 and the second section 1212 can be substantially perpendicular to each other) to correspond to the sliding rail 151 of the bracket 150. In some embodiments, the lengths of the first section 1211 and the second section 1212 may be different, but the present disclosure is not limited thereto. In other words, the connecting portion 121 may include a plurality of segments (such as the first segment 1211 and the second segment 1212) extending in different directions, thereby reducing the risk of separation of the holder 120 and the bracket 150 during movement.

In addition, the handle 140 can be coupled to the frame 110 through the axial member 145. The axial member 145 can pass through the opening 143 of the handle 140. As a result, the user can utilize the handle 140 to operate the holding mechanism 100. For example, the axial member 145 may include a nut 145A and a bolt 145B that are combined with each other, but the present disclosure is not limited thereto. In other embodiments, the axial member 145 may be a one-piece component. The torsion member 130 abuts against the axial member 145 and is used to continuously apply a torque on the axial member 145 to keep the handle 140 in a proper position. For example, the torsion member 130 may be a torsion spring. In some embodiments, one end of the torsion member 130 may be connected to the handle 140 and the other end of the torsion member 130 may be connected to the frame 110 (for example, the bottom surface 111 of the frame 110), but the present disclosure is not limited thereto. It should be understood that the torsion member 130 can be any element that can apply a torque, and all configurations applicable to apply a torque to the axial member 145 are included within the scope of the present disclosure.

In addition, the holder 120 is movably connected to the bracket 150 via the connecting portion 121. Specifically, the connecting portion 121 of the holder 120 can be coupled to the sliding rail 151 of the bracket 150, whereby the holder 120 is movable along the trajectory of the sliding rail 151. The sliding member 160 has a sliding groove 161 extending along a first direction (for example, parallel to the X-axis), wherein the locking member 162 may pass through the sliding groove 161 and the bracket 150 to connect the sliding member 160 and the bracket 150. The elastic element 170 may connect the bracket 150 and the sliding member 160 in the first direction (for example, the X direction). In some embodiments, the sliding member 160 is movable in the first direction (in which the sliding groove 161 extends) relative to the bracket 150. For example, the user can apply a force on the force application end 141 of the handle 140 to push the protruding portion 163 of the sliding member 160 via the abutting end 142. As a result, the sliding member 160 is movable relative to the bracket 150. The operation mode of the holding mechanism 100 will be further described below with reference to FIGS. 7A through 7D.

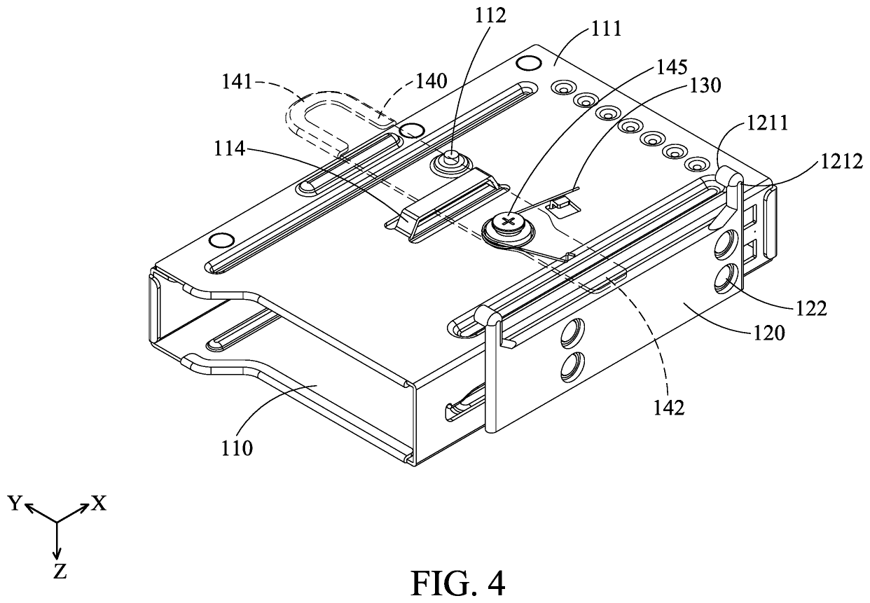

FIG. 4 illustrates a perspective view of the holding mechanism 100 in accordance with some embodiments of the present disclosure. It should be noted that in order to clearly show the structure of the frame 110, this embodiment merely illustrates the partial structure of the holding mechanism 100, and the frame 110 is turned upside down (for example, with the negative Z direction facing upward) to show the bottom surface 111 of the frame 110. As shown in FIG. 4, a stopper 112 and a limiting portion 114 are disposed on the bottom surface 111 of the frame 110. In some embodiments, the stopper 112 protrudes from the bottom surface 111. Since the torsion member 130 will continuously apply a torque (for example, in a clockwise direction) on the axial member 145 (and the handle 140), the stopper 112 may be used to stop the handle 140 to maintain the handle 140 and the frame 110 connected to the handle 140 in a proper location. It should be understood that although this embodiment illustrates one stopper 112, any suitable structure and number of the stopper 112 are included within the scope of the present disclosure.

In addition, in some embodiments, the limiting portion 114 protrudes from the bottom surface 111 and the handle 140 can pass through the limiting portion 114. Accordingly, the rotation angle of the handle 140 is limited, so that the handle 140 can effectively push the sliding member 160 (which will be described later) to drive the frame 110 to move, thereby reducing the risk of the handle 140 being displaced and failing to operate normally. The handle 140 has a force application end 141 and a abutting end 142 located on both sides of the axial member 145. The user can apply a force on the force application end 141 of the handle 140 to operate the handle 140. In some embodiments, the linear distance between the force application end 141 and the axial member 145 (for example, a fulcrum) may be greater than the linear distance between the abutting end 142 and the axial member 145, thereby achieving a labor-saving effect. However, the present disclosure is not limited thereto. The handle 140 may adopt any suitable lever configuration, and all possible configurations will not be individually enumerated below.

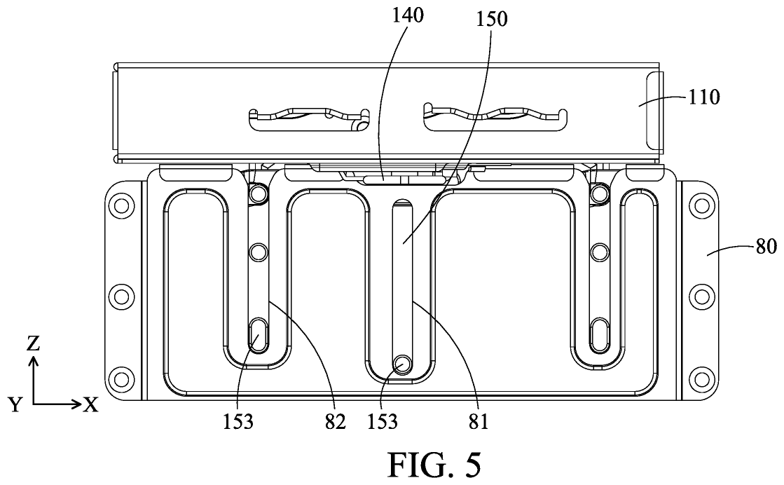

FIG. 5 illustrates a side view of the holding mechanism 100 in accordance with some embodiments of the present disclosure. As shown in FIG. 5, the fixed bracket 80 has a groove 81, and the groove 81 is used to receive the positioning portion 153 of the bracket 150. In some embodiments, the groove 81 extends in a third direction (for example, parallel to the Z-axis) that is perpendicular to the first direction (for example, parallel to the X-axis). The groove 81 may be closed to define the movement range of the bracket 150 using the positioning portion 153 so that the holding mechanism 100 is movably disposed between the fixed bracket 80 and the sidewall 52. In some embodiments, the fixed bracket 80 is provided with a plurality of slots 82, and the slots 82 are used to receive other positioning portions 153 of the bracket 150. Although this embodiment illustrates one groove 81 and two slots 82, it should be understood that the number and configuration of the groove 81 and the slots 82 are not limited thereto.

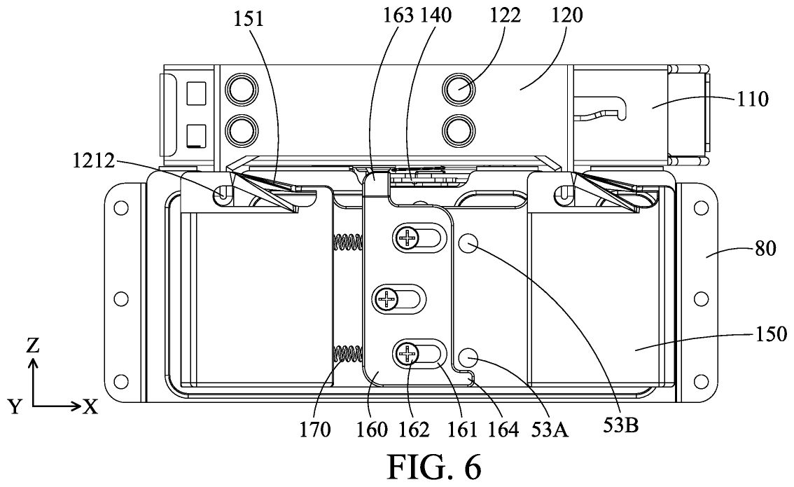

FIG. 6 illustrates a side view of the holding mechanism 100 in accordance with some embodiments of the present disclosure. As shown in FIG. 6, the sliding member 160 has a protruding portion 163 and a positioning portion 164. The protruding portion 163 may extend in the third direction (for example, parallel to the Z-axis), and the positioning portion 164 may extend in the first direction (for example, parallel to the X-axis). A plurality of positioning pins 53A and 53B may be disposed on the sidewall 52 of the chassis 50 (for example, referring to FIG. 1). The positioning pins 53A and 53B are arranged in the second direction (for example, parallel to the Y-axis). When the positioning pins 53A and 53B are assembled on the sidewall 52 of the chassis 50, the positioning pin 53A is adjacent to the bottom surface 51 and the positioning pin 53B is away from the bottom surface 51. In some embodiments, the elastic element 170 can continuously apply a thrust to the sliding member 160 (for example, in a direction parallel to the X-axis), so that the positioning portion 164 is located between the positioning pin 53A and the bottom surface 51. As a result, the positioning pin 53A is used to limit the positioning portion 164 so that the sliding member 160 and the bracket 150 cannot move in the second direction (for example, parallel to the Y-axis), thereby maintaining the holding mechanism 100 in the storage state.

FIGS. 7A through 7D illustrate schematic views of various stages of operating the holding mechanism 100 in accordance with some embodiments of the present disclosure. As shown in FIG. 7A, when the user operates the handle 140 (for example, the apply force application end 141), the handle 140 (for example, the abutting end 142) pushes the protruding portion 163, thereby pushing the sliding member 160 and compressing the elastic element 170. Accordingly, the positioning portion 164 moves away from the positioning pin 53A, which makes the holding mechanism 100 in a movable free state. Next, as shown in FIG. 7B, the user may continue to operate the handle 140 or lift the frame 110 of the holding mechanism 100 in the third direction (for example, the Z direction) with bare hands until the positioning portion 153 of the bracket 150 abuts the top (not labeled) of the groove 81. At this time, the user can release the handle 140 (or the frame 110). The thrust provided by the elastic element 170 will return the sliding member 160 to its original position, and the positioning portion 164 will locate on the positioning pin 53B to position the holding mechanism 100.

Next, as shown in FIG. 7C, the user can apply a force on the handle 140 (or the frame 110), so that the holder 120 and the frame 110 may rotate relative to the bracket 150 along the sliding rail 151 to the unfolded state while the connecting portion 120 serves as the fulcrum. At this time, the frame 110 can be located outside the sidewall 52 without overlapping the bottom surface 51 in the third direction (for example, the Z-axis direction) to facilitate the installation or removal of the electronic component 60 (for example, referring to FIG. 7D). As shown in FIG. 7D, the electronic component 60 can be installed in the frame 110 without being interfered by other components in the chassis 50, which greatly improves the convenience of installing or removing the electronic component 60. However, the present disclosure is not limited thereto. The user can install the electronic component 60 in the holding mechanism 100 or remove the electronic component 60 from the holding mechanism 100 in any state described in the present disclosure.

It should be understood that after completing the installation or removal of the electronic component 60, the user can return the holding mechanism 100 to its original position according to the reversed process of the above steps. For example, the user can rotate the holder 120 and the frame 110 along the sliding rail 151 with the connecting portion 121, operate the handle 140 (for example, the force application end 141), and move the positioning portion 164 away from the positioning pin 53B, so that the holding mechanism 100 is in the movable free state. Then, the holding mechanism 100 is moved in the third direction (for example, the Z-axis direction) until the positioning portion 153 of the bracket 150 abuts against the top (not labeled) of the groove 81. The thrust provided by the elastic element 170 causes the sliding member 160 to return to its original position and abut against the positioning pin 53A, keeping the holding mechanism 100 in the storage state. However, the present disclosure is not limited thereto. The user can position the holding mechanism 100 at any position described in the present disclosure depending on operation requirements.

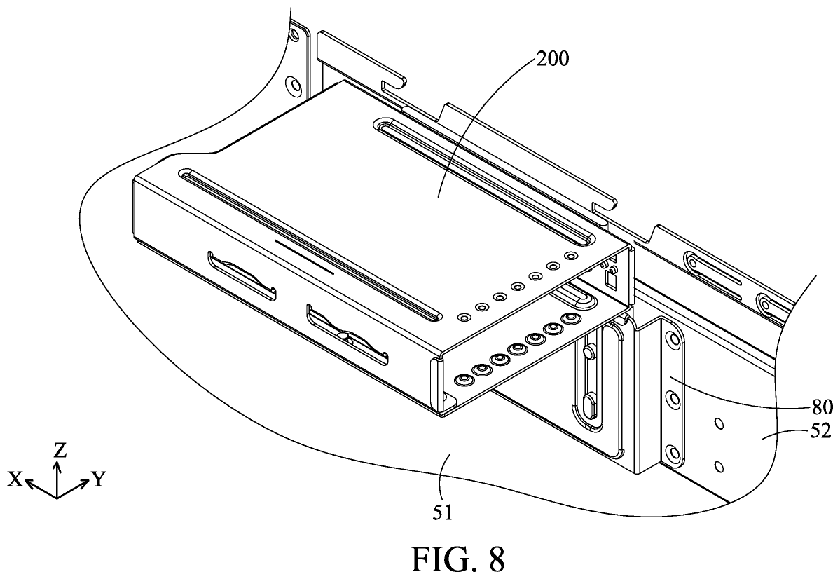

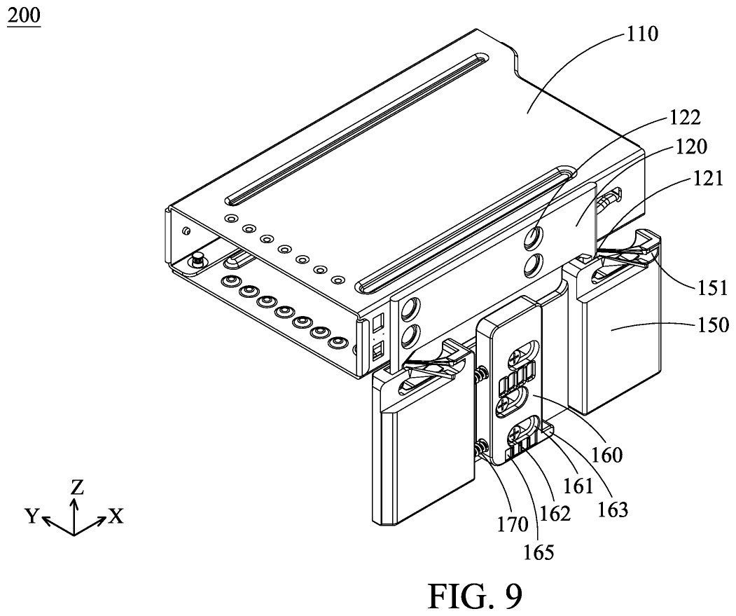

FIG. 8 illustrates a partial perspective view of the electronic device 10 in accordance with some embodiments of the present disclosure. In this embodiment, the holding mechanism 200 is disposed in the electronic device 10 instead of the holding mechanism 100 and is movably disposed between the fixing bracket 80 and the sidewall 52. As shown in FIG. 8, at this time, the holding mechanism 200 is in the storage state. The detailed structure of the holding mechanism 200 will be further described below with reference to FIG. 9.

FIG. 9 illustrates a perspective view of the holding mechanism 200 in accordance with some embodiments of the present disclosure. It should be noted that the holding mechanism 200 in this embodiment may include elements or portions that are the same as or similar to those of the holding mechanism 100 in the above embodiment. These elements or portions will be denoted by the same or similar reference numerals and will not be described in detail below. As shown in FIG. 9, the holding mechanism 200 may include a frame 110, a holder 120, a bracket 150, a sliding member 160 and an elastic element 170. In other words, compared with the holding mechanism 100, the holding mechanism 200 omits the torsion member 130 and the handle 140, thereby simplifying the structure and reducing the cost. In some embodiments, a plurality of operating portions 165 are disposed on a surface (for example, parallel to the X-Z plane) of the sliding member 160 of the holding mechanism 200. In some embodiments, the operating portions 165 can be parallel to each other and each have a plurality of grooves (for example, recessed from the above-mentioned surface of the sliding member 160), so as to facilitate the user to apply a force on the sliding member 160 to operate the holding mechanism 200. For example, the operating portions 165 may extend in the first direction (for example, parallel to the X-axis). As a result, the user can apply a force on the sliding member 160 in the first direction (for example, parallel to the X-axis) using the operating portion 165 with bare hands. However, the present disclosure is not limited thereto.

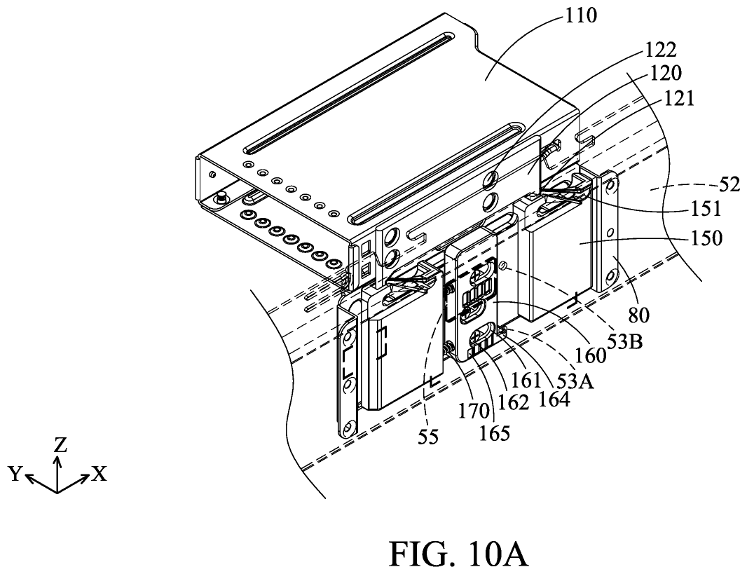

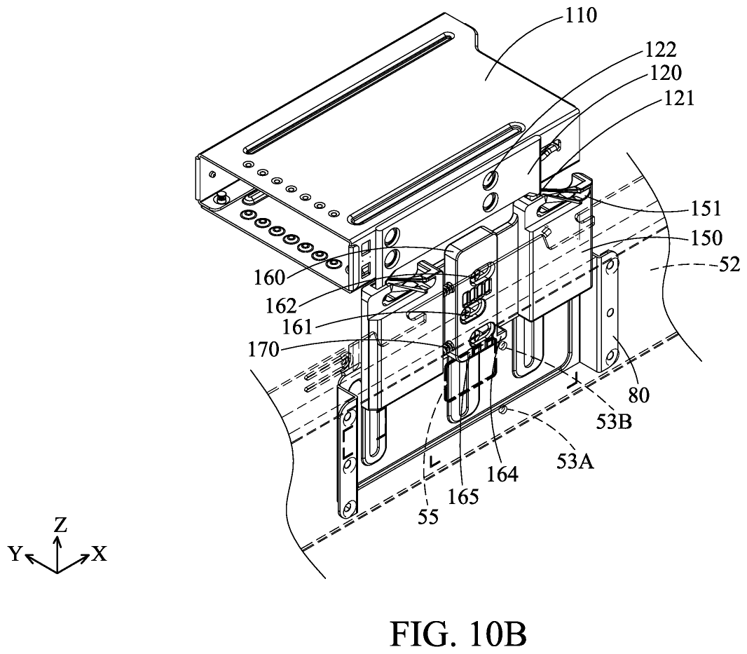

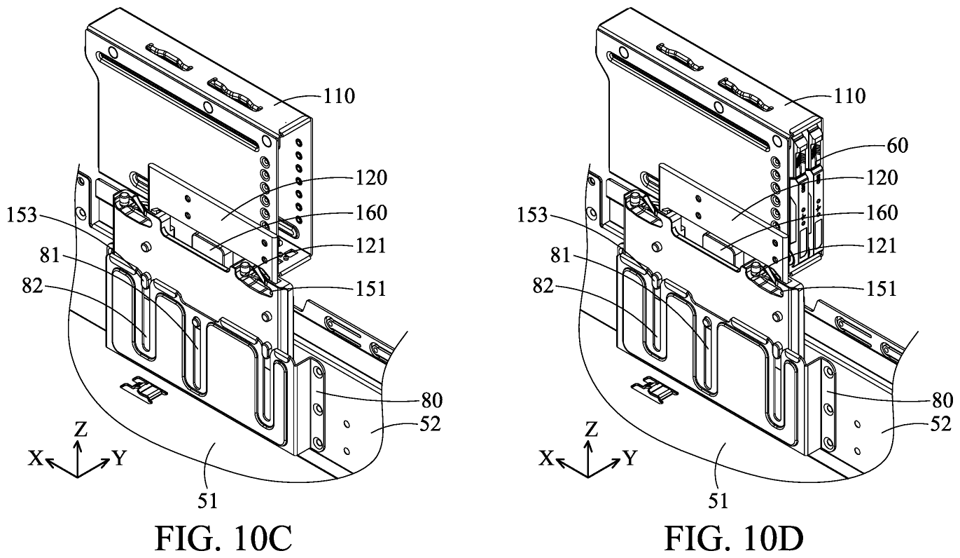

FIGS. 10A through 10D illustrate schematic views of various stages of operating the holding mechanism 200 in accordance with some embodiments of the present disclosure. As shown in FIG. 10A, the user can apply a force on the sliding member 160 (such as the operating portions 165) through the opening 55 on the sidewall 52 to push the sliding member 160 and compress the elastic element 170, moving the positioning portion 164 away from the positioning pin 53A. At this time, the holding mechanism 200 is in the movable free state. That is, in this embodiment, the opening 55 will expose one of the operating portions 165. In some embodiments, the size of the opening 55 is larger than the size of one of the operating portions 165 in a plane substantially parallel to the sidewall 52 (for example, the X-Z plane). However, the present disclosure is not limited thereto.

Next, as shown in FIG. 10B, the user can simultaneously lift the frame 110 while applying a force to the sliding member 160 to lift up the holding mechanism 200 until the positioning portion 153 of the bracket 150 abuts against the top (not labeled) of the groove 81. At this time, the user can loosen the sliding member 160, and the thrust provided by the elastic element 170 causes the sliding member 160 to automatically return to its original position, and the positioning portion 164 locates on and abut to the positioning pin 53B to position the holding mechanism 200. When the holding mechanism 200 is lifted, the opening 55 will expose the other of the operating portions 165. It should be understood that this embodiment illustrates one configuration of the opening 55, but the present disclosure is not limited thereto. In other embodiments, a plurality of openings 55 may be disposed on the sidewall 52, each of which corresponds to different operating portions 165. At this time, the size of the opening 55 may be each larger than or equal to the size of the corresponding one of the operating portions 165.

Next, as shown in FIG. 10C, the user can apply a force on the frame 110, so that the holder 120 and the frame 110 rotate relative to the bracket 150 along the sliding rail 151 to the unfolded state while the connecting portion 121 serves as a fulcrum. At this time, the frame 110 can be located outside the sidewall 52 without overlapping the bottom surface 51 in the third direction (for example, the Z-axis direction) to facilitate the installation or removal of the electronic component 60 (for example, referring to FIG. 10D). As shown in FIG. 10D, the electronic component 60 can be installed in the frame 110 without being interfered by other components in the chassis 50, which greatly improves the convenience of installing or removing the electronic component 60. However, the present disclosure is not limited thereto. The user can install the electronic component 60 in the holding mechanism 200 or remove the electronic component 60 from the holding mechanism 200 in any state described in the present disclosure.

It should be understood that after completing the installation or removal of the electronic component 60, the user can return the holding mechanism 200 to its original position according to the reversed process of the above steps. For example, the user can rotate the holder 120 and the frame 110 along the sliding rail 151 while the connecting portion 121 serves as the fulcrum, and apply a force on the sliding member 160 so that the holding mechanism 200 is in the movable free state. Then, the holding mechanism 200 is moved in the third direction (for example, the Z-axis direction) until the positioning portion 153 of the bracket 150 abuts against the bottom (not labeled) of the groove 81. At this time, the thrust provided by the elastic element 170 will return the sliding member 160 to its original position and abut against the positioning pin 53A, and the positioning portion 164 will be restricted by the positioning pin 53A, keeping the holding mechanism 200 in the storage state. However, the present disclosure is not limited thereto. The user can position the holding mechanism 200 at any position described in the present disclosure depending on operation requirements.

As set forth above, the present disclosure provides a holding mechanism and an electronic device that are movable to install or remove electronic components. With the holding mechanism of the above embodiment, the electronic device (such as a chassis) can accommodate additional electronic components without occupying the area on the bottom surface. As a result, the space of other components originally installed in the electronic device will not be affected. In addition, the frame of the holding mechanism can be rotated out of the electronic device, greatly improving the convenience of installing or removing electronic components.

While the embodiments and the advantages of the present disclosure have been described above, it should be understood that those skilled in the art may make various changes, substitutions, and alterations to the present disclosure without departing from the spirit and scope of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. As long as those may perform substantially the same function in the aforementioned embodiments and obtain substantially the same result, they may be used in accordance with some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. A holding mechanism, for accommodating an electronic component, comprising:
a frame used to accommodate the electronic component;
a holder affixed to the frame; and
a bracket having a slide rail, wherein the holder is connected to the bracket via the slide rail, so that the frame is rotatable relative to the bracket.

2. The holding mechanism as claimed in claim 1, further comprising a sliding member movably disposed on the bracket.

3. The holding mechanism as claimed in claim 2, further comprising a handle rotatably disposed on a bottom surface of the frame.

4. The holding mechanism as claimed in claim 3, wherein a stopper is disposed on the bottom surface of the frame and used to stop the handle.

5. The holding mechanism as claimed in claim 3, wherein the sliding member has a protruding portion, and the protruding portion is pushed by the handle so that the sliding member is movable relative to the bracket.

6. The holding mechanism as claimed in claim 2, wherein a plurality of operation portions are disposed on a surface of the sliding member, and the operation portions are parallel to each other.

7. The holding mechanism as claimed in claim 1, wherein the holder has a connecting portion, and the holder is connected to the slide rail of the bracket via the connecting portion.

8. The holding mechanism as claimed in claim 7, wherein the connecting portion comprises a first section and a second section that extend in different directions.

9. The holding mechanism as claimed in claim 8, wherein the holder is rotated along the slide rail while the connecting portion serves as a fulcrum, when the holding mechanism is in a storage state, the connecting portion is connected to the slide rail via the first section, and when the holding mechanism is in an unfolded state, the connecting portion is connected to the slide rail via the second section.

10. An electronic device, comprising:
a chassis having a bottom surface and a sidewall perpendicular to the bottom surface;
a fixed bracket affixed on the sidewall; and
a holding mechanism movably connected to the fixed bracket and comprising:
a frame used to accommodate an electronic component;
a holder affixed to the frame; and
a bracket movably disposed between the sidewall of the chassis and the fixed bracket,
wherein the bracket has a slide rail, and the holder is movably connected to the bracket via the slide rail, so that the holding mechanism is rotatable relative to the chassis.

11. The electronic device as claimed in claim 10, wherein when the fixed bracket has a groove, the groove is used to receive a positioning portion of the bracket, so that the bracket is slidably disposed on the fixed bracket.

12. The electronic device as claimed in claim 10, wherein the holding mechanism further comprises a sliding member movably disposed on the bracket, and the sliding member is located between the bracket and the sidewall.

13. The electronic device as claimed in claim 12, wherein the sliding member has a positioning portion and a protruding portion, and the positioning portion and the protruding portion extend in different directions.

14. The electronic device as claimed in claim 13, wherein a plurality of positioning pins are disposed on the sidewall, and the positioning portion of the sliding member is limited by the positioning pins to position the holding mechanism.

15. The electronic device as claimed in claim 13, wherein the holding mechanism further includes:
a handle disposed on a bottom surface of the frame, wherein the handle is used to push against the protruding portion of the sliding member so that the sliding member is away from the positioning pins.

16. The electronic device as claimed in claim 12, wherein a plurality of operating portions are disposed on a surface of the sliding member, and the operating portions are parallel to each other.

17. The electronic device as claimed in claim 16, wherein the sidewall has an opening, and the opening exposes one of the operating portions.

18. The electronic device as claimed in claim 10, wherein the holder has a connecting portion, and the holder is connected to the slide rail of the bracket via the connecting portion.

19. The electronic device as claimed in claim 18, wherein the connecting portion comprises a first section and a second section that extend in different directions.

20. The electronic device as claimed in claim 19, wherein the holder is rotated along the slide rail while the connecting portion serves as a fulcrum, when the holding mechanism is in a storage state, the connecting portion is connected to the slide rail via the first section, and when the holding mechanism is in an unfolded state, the connecting portion is connected to the slide rail via the second section.
